(19) United States
(12) Patent Application Publication
(10) Pub. No.: US 2025/0140567 A1
(43) Pub. Date: May 1, 2025

(54) MULTI-PARAMETER IMPLANTATION FOR MANAGING WAFER DISTORTION

(71) Applicant: Applied Materials, Inc., Santa Clara, CA (US)

(72) Inventors: Stanislav S. TODOROV, Topsfield, MA (US); Wonjae LEE, Fremont, CA (US); Pradeep SUBRAHMANYAN, Cupertino, CA (US); D. Jeffrey LISCHER, Acton, MA (US)

(73) Assignee: Applied Materials, Inc., Santa Clara, CA (US)

(21) Appl. No.: 18/498,813

(22) Filed: Oct. 31, 2023

(51) Int. Cl. H01L 21/3115; H01J 37/24; H01J 37/317

(52) U.S. Cl. CPC H01L 21/31155; H01J 37/24; H01J 37/3171; H01J 2237/0473

(57) ABSTRACT

A a method of stress management in a substrate. The method may include providing a stress compensation layer on a main surface of the substrate; and performing a chained implant procedure to implant a set of ions into the stress compensation layer. The chained implant procedure may include directing a first implant procedure to the substrate, the first implant procedure generating a first damage profile within the stress compensation layer; directing a second implant to the substrate, different from the first implant, wherein a composite damage profile is generated within the stress compensation layer after the second implant, the composite damage profile resulting in a higher stress response ratio than the first damage profile.

### FIELD

The present embodiments relate to stress control in substrates, and more particularly to stress compensation to reduce out-of-plane distortion in substrates.

### BACKGROUND

Devices such as integrated circuits, memory devices, and logic devices may be fabricated on a substrate such as a semiconductor wafer by a combination of deposition processes, etching, ion implantation, annealing, and other processes. Often, complete fabrication of devices and related circuitry may entail many hundreds of operations, including dozens of lithography operations. In particular, lithographic operations may require that a given mask to fabricate structures in a given region or level is to be aligned to preexisting structures.

A resulting problem with fabrication of substrates is the development of out-of-plane distortion (OPD) caused by stresses within the wafer, which distortion may be referred to as warpage. This OPD may be a result of stress that develops within the wafer as a result of processing. As a result, management of OPD may be critical to achieve proper overlay between structures fabricated at different levels of a device. For example, a type of OPD often encountered is a global wafer curvature that may develop at many instances of processing due to stress buildup in the wafer as a result of processing operations.

One approach to managing wafer (substrate) stress is to provide a stress compensation layer on the back of a substrate, which layer may be used counteract existing stress within the substrate and thus reduce OPD. In particular implementations, ion implantation has been used to implant ions into the stress compensation layer in order to attempt to alter the stress state in the stress compensation layer and thus indirectly change the stress and OPD in the substrate. However, ion implantation inherently generates non-uniformity within the thickness of an implanted layer such as a stress compensation layer, where such non-uniformity is not taken into account in the current approaches.

With respect to these and other considerations the present embodiments are provided.

### BRIEF SUMMARY

In one embodiment, a method is provided. The method may include providing a stress compensation layer on a main surface of the substrate; and performing a chained implant procedure to implant a set of ions into the stress compensation layer. The chained implant procedure may include directing a first implant procedure to the substrate, the first implant procedure generating a first damage profile within the stress compensation layer; directing a second implant to the substrate, different from the first implant, wherein a composite damage profile is generated within the stress compensation layer after the second implant, the composite damage profile resulting in a higher stress response ratio than the first damage profile.

In another embodiment, an ion implanter is provided. The ion implanter may include an ion source to generate an ion beam; an acceleration component to vary an ion energy of the ion beam and a controller. The controller may include comprising a processor; and a memory unit coupled to the processor, including a chained implant routine, the chained implant routine operative on the processor to control the ion implanter to impart a composite damage profile into a stress compensation layer on a substrate by performing a plurality of implants at a plurality of different ion implant conditions. As such, a first implant may be to generate a first damage profile within the stress compensation layer, and a second implant may be to generate a composite damage profile after the second implant, the composite damage profile having a higher stress response ratio than the first damage profile.

In a further embodiment, a controller for an ion implanter is provided. The controller may include a processor; and a memory unit coupled to the processor, including a chained implant routine, the chained implant routine operative on the processor to control an ion implanter to impart a composite damage profile into a stress compensation layer on a substrate. The composite profile may be implemented by: performing a first implant under a first set of implant conditions; and performing a second implant under a second set of implant conditions, different from the first set of implant conditions. As such, the first implant may be to generate a first damage profile within the stress compensation layer, and the second implant may be to generate a composite damage profile after the second implant, where the composite damage profile results in a higher stress response ratio than the first damage profile.

### BRIEF DESCRIPTION OF THE DRAWING

FIG. 1 shows an exemplary system in accordance with the present disclosure;

FIG. 1A shows further details of a controller according to some embodiments of the disclosure;

FIG. 2A shows an example of a stress state in a substrate;

FIG. 2B shows the geometry for managing stress in a substrate;

FIG. 2C shows an example of a substrate shape as the result of ion implantation to properly compensate for an initial substrate stress as in FIG. 2B.

FIG. 3 is a graph that illustrates the use of complementary implants according to the present embodiments to improve distribution of damage within a layer;

FIG. 4 is a graph that illustrates the use of ion implantation to achieve defect saturation using a single implant approach;

FIG. 5 presents a graph providing a pictorial representation of the stress response ratio;

FIG. 5A plots the dependence of the stress response ratio as a function of total ion dose;

FIG. 6 is a graph that illustrates the use of a two-implant chained ion implantation approach to achieve more efficient defect saturation within a layer, according to embodiments of the disclosure;

FIG. 7 is a graph that illustrates the use of complementary implants according to additional embodiments of the disclosure to improve distribution of damage within a layer;

FIG. 8 is a graph that illustrates the use of the four-implant chained ion implantation approach of FIG. 7 to achieve more efficient defect saturation within a layer, according to embodiments of the disclosure;

FIG. 9 is a graph that illustrates the use of complementary implants according to additional embodiments of the disclosure to improve distribution of damage within a layer;

FIG. 10 is a graph that displays the results of such an approach according to further embodiments of the disclosure;

FIG. 11 depicts an exemplary process flow; and

FIG. 12 depicts a further exemplary process flow.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. Instead, these embodiments are provided so this disclosure will be thorough and complete, and will fully convey the scope of the subject matter to those skilled in the art. In the drawings, like numbers refer to like elements throughout.

The embodiments described herein relate to techniques and apparatus for improved substrate stress management. The present embodiments present an approach that employs a novel set of implants into a layer provided on a substrate in order to improve stress relief in the substrate. In particular, a set of chained implants may be performed using a beamline ion implanter to optimize the distribution of damage in the implanted layer in a manner to more effectively treat substrate stress.

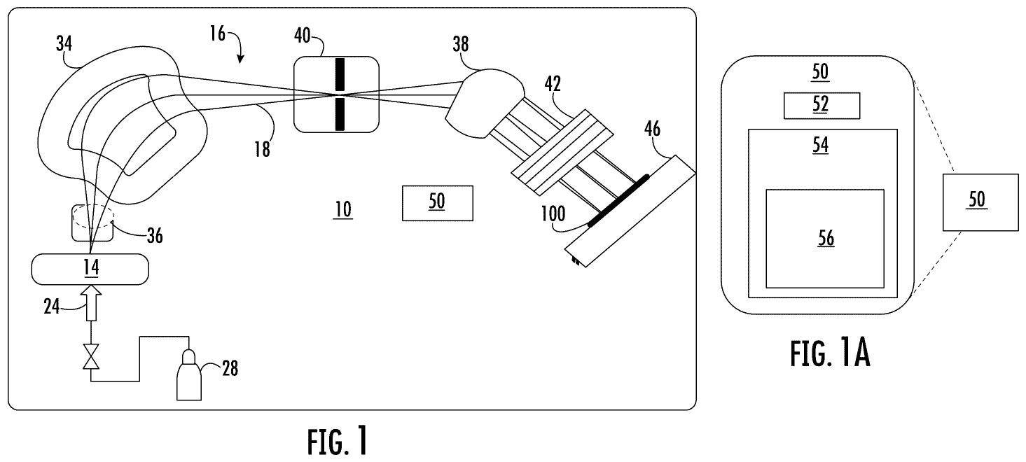

Referring now to FIG. 1, an exemplary system in accordance with the present disclosure is shown. The ion implantation system (hereinafter “system”) 10 represents a process chamber containing, among other components, an ion source 14 for producing an ion beam 18, an ion implanter, and a series of beam-line components 16. The ion source 14 may comprise a chamber for receiving a flow of gas 24 and generating ions therein. The ion source 14 may also comprise a power source and an extraction electrode assembly disposed near the chamber. The beam-line components 16 may include, for example, a mass analyzer 34, a first acceleration or deceleration stage 36, a collimator 38, a mass resolving slit 40, and other suitable downstream beamline components such as an energy filter 42, to accelerate the ion beam 18, decelerate the ion beam 18, shape the ion beam 18, scan the ion beam 18, and so forth.

In particular embodiments, the beam-line components 16 may filter, focus, accelerate, decelerate, and otherwise manipulate ions or the ion beam 18 to have a desired species, shape, energy, and other qualities. The ion beam 18 passing through the beam-line components 16 may be directed toward a substrate mounted on a platen or clamp within a process chamber 46. As appreciated, the substrate may be moved in one or more dimensions (e.g., translate, rotate, and tilt).

As shown, there may be one or more feed sources 28 operable with the chamber of the ion source 14.

In various embodiments, different species may be used as the ions to be used to process the stress in the film. Non-limiting examples of suitable ions include silicon (Si), boron (B), carbon (C), oxygen (O), germanium (Ge), phosphorus (P), arsenic (As), and so forth as to control substrate stress.

Although non-limiting, the ion source 14 may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma sources known to those skilled in the art.

The ion source 14 may generate the ion beam 18 for processing a substrate. In various embodiments, the ion beam (in cross-section) may have a targeted shape, such as a spot beam or ribbon beam, as known in the art. In the Cartesian coordinate system shown, the direction of propagation of the ion beam 18 may be represented as parallel to the Z-axis, while the actual trajectories of ions with the ion beam 18 may vary. In order to process the substrate, the ion beam 18 may be accelerated to acquire a target energy by establishing a voltage (potential) difference between the ion source 14 and the wafer (substrate).

As further shown in FIG. 1, the system 10 may include a controller 50 to control operation of various components of the system 10, including components to scan the platen, to tilt the platen, to scan the ion beam 18, or to adjust the energy of the ion beam 18, for example. FIG. 1A provides details of an embodiment of the controller 50, discussed further below.

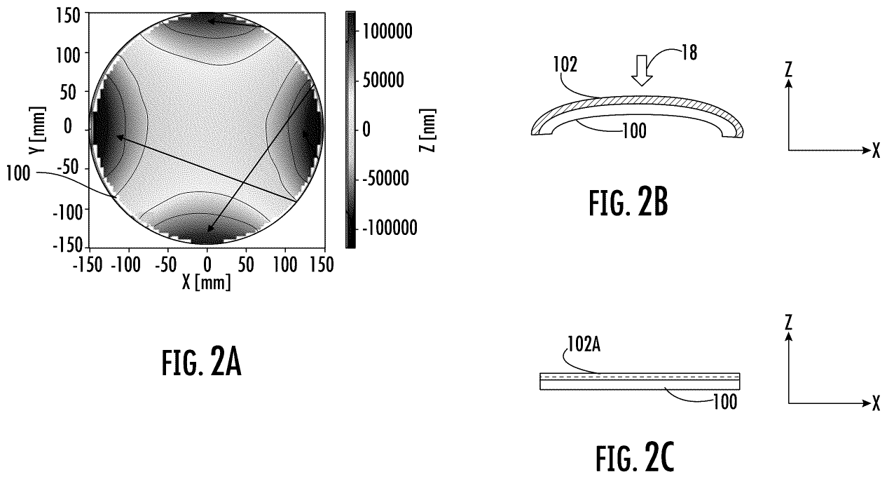

Turning to FIG. 2A there is shown an example of a stress state in a substrate. In this example, the stress state may be represented by a pattern of OPD. In the example of FIG. 2A the OPD has a symmetrical configuration where a negative OPD is seen in vertical football shaped regions to the left and right periphery of the substrate 100, and a positive OPD is observed in horizontal football shaped regions to the upper and lower periphery of the substrate 100. The example stress pattern of FIG. 2A is provided for the purposes of illustration, while in general of substrate 100 may be characterized by simpler stress patterns, or by more complex stress patterns where stress and OPD vary in more complex patterns.

In various embodiments detailed herein a beamline ion implanter is used to perform a series of implants, which implants may be deemed chained implants, in order to adjust the stress state in a substrate. Turning to FIG. 2B there is shown the geometry for managing stress in a substrate 100. In this example, the ion beam 18 is directed to the substrate 100, and in particular to a layer 102, disposed on a main surface of the substrate 100. The layer 102 may be an oxide layer or a nitride layer according to some non-limiting embodiments, such as silicon nitride (hereinafter referred to also as “SiN”). The layer 102 may be deposited on the substrate in a stressed state so as to change the overall stress state of the substrate 100. The layer 102 may then act as a medium to receive an implant dose of ions, so as to change the stress state in the layer 102, and thus to further change the stress state in the substrate 100. As such, the layer 102 may be deemed to constitute a stress compensation layer (SCL). As illustrated in FIG. 2B, the substrate may exhibit curvature in the X-Z plane of the Cartesian coordinate system shown, leading to OPD. In particular embodiments, the layer 102 may be deliberately formed in a relatively higher stress state, which stress state will impart a relatively greater curvature into the substrate 100. In so doing, the changes is the stress state of layer 102 and therefore changes in curvature of the substrate 100 may be enhanced for a given set of ion implantation conditions, discussed below.

The curvature shown in FIG. 2B may be global, as well as local and may extend in a two-dimensional pattern as shown in FIG. 2A. As an example, the substrate 100 may include device structures to be fabricated, or in the process of being fabricated on the substrate 100, where these devices are located on the main surface of the substrate 100, opposite to layer 102. As such, one goal may be to reduce curvature of the substrate 100, thus reducing OPD and aiding in device processing. An example of a properly treated state of the substrate 100 is shown in FIG. 2C, where the substrate 100 is depicted as flat, which shape may be the result of ion implantation into layer 102 to properly compensate for initial substrate stress illustrated in FIG. 2B.

According to embodiments of the disclosure, the ion beam 18 may be directed to the layer 102 in a series of chained implants that reduce the stress within the substrate 100. The chained implants may be performed in a manner to more uniformly distribute damage within the layer 102, and thus more efficiently control the stress.

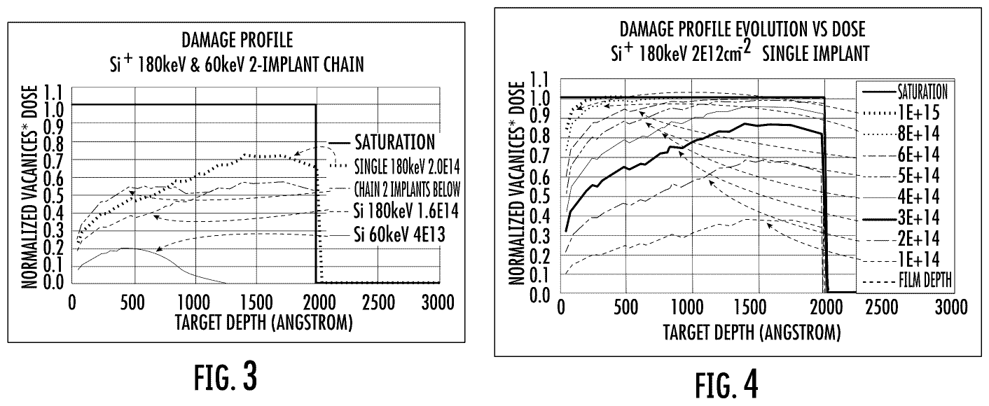

FIG. 3 is a graph that illustrates the use of complementary implants according to the present embodiments to improve distribution of damage within a layer. In particular, the graph plots a simulation of the normalized vacancies generated by Si ion implantation as a function of depth within a 2000 Å thick SiN layer. The parameter of “normalized vacancies” as used herein may be understood as a ratio of the actual vacancy level in a layer divided by the threshold vacancy level of that layer beyond which further stress changes in the layer no longer occur. The threshold vacancy level may be determined empirically for a given material.

The total dose of the chained implant is 2E14/cm³. The chained implant is formed as the sum of two implants, where one implant is performed at 60 keV to implant a dose of 4E13/cm² Si ions into the silicon nitride layer. Another implant is performed at 180 keV to implant a dose of 1.6E14/cm² Si ions into the silicon nitride layer. The lower energy implant, indicated by the lowest curve, generates a distribution of vacancies in the direction normal to the layer surface, which distribution may be referred to as a damage profile. The damage profile peaks in concentration at a value of 0.2 at approximately 500 Å depth from the upper surface of the SiN layer. The higher energy implant generates a damage profile peaks in concentration at a value of 0.56, at approximately 1600 Å depth. Together, the chained implant, representing a sum of the two profiles, generates a relatively flat damage profile that exhibits a plateau at a value of 0.53+/−0.03 at depths greater than 450 Å. For comparison, FIG. 3 also shows a curve that represents the damage profile induced after a single implant of 2E14/cm² Si ions at an energy of 180 keV. Again, the damage profile peaks at approximately 1600 Å depth, with a peak value of 0.71.

Note that in the example of FIG. 3, for the same total Si ion dose (2E14/cm²), the use of two different implants, with varying energy as described, results in a much more uniform damage profile, albeit with a lower peak value. The approach illustrated in FIG. 3 may be extended to improve and optimize the stress state in a layer, such as a stress compensation layer. The present inventors have appreciated that ion beam bombardment of a stress compensation layer produces collision cascades within the stress compensation layer, which cascades enable the relocation of layer atoms from an initial higher-energy position, to energetically more stable positions, thus lowering the wafer stress. Moreover, in some embodiments generating a uniform damage distribution within a stress reduction layer may be called for, meaning the damage distribution is the same—in dose and depth—at all points across a wafer.

In the example of single implant of 2E14/cm² shown in FIG. 3, the maximum of the damage profile is near located the film/substrate interface. However, there is significant variation of damage with depth, where the normalized damage is much lower at depths below 1400 A. While the integrated damage for the single implant condition of FIG. 3 may be somewhat higher than in the chained implant case, and may be expected to yield a higher amount of stress reduction, the more uniform distribution of vacancies as a function of depth in the chained implant example may be useful for (please fill in the blank)

Note that in addition to generating a more uniform damage profile when called for, generating a layer with maximum damage or defects to facilitate maximum stress relief may be useful. Referring again to FIG. 3, the maximum or saturated defect state may be expressed by the saturation curve, where the normalized vacancy value is 1 across the thickness of the 2000 A-thick SiN layer. To achieve a damage state approximating or approaching the saturation curve, more than one implant procedure may be required.

FIG. 4 is a graph that illustrates the use of ion implantation to achieve defect saturation using a single implant approach. In particular, as with FIG. 3, the graph plots a simulation of the normalized vacancies generated by Si ion implantation as a function of depth within a 2000 Å thick SiN layer. The ion energy of the single implant is 180 keV, and a series of curves are shown representing the dose profiles that exist after a given total dose of Si ions has been implanted into the SiN layer. The lowest curve represents a total dose of 1E14/cm², while the highest curve represents a total dose of 1E15/cm³. The series of curves thus represent the evolution of a damage profile as a function of total dose. Note that at relatively lower total dose, the damage saturates for relatively greater depths within the SiN. For example, using a normalized vacancy value of 0.9 as a threshold for very saturated defect level, this value is exceeded at depths greater than 700 A for a dose of 5E14/cm². However, higher dose levels just slowly increase the normalized vacancy value at depths greater than 700 A, while gradually increasing the normalized vacancy value at shallower depths. In sum, the single-implant results shown in FIG. 4 depicts a saturation behavior of net defect creation that is first exhibited at the stress compensation layer region(s) subjected to the harshest ion bombardment.

This single-implant approach thus suffers from a possible inefficiency at imparting damage throughout the depth of the layer, especially at relatively shallower or greater depths where the damage profile tends to be low. The behavior of FIG. 4 may be expressed as a response phenomenon, where an implanted layer may be characterized by a stress response ratio (SRR). The stress response ratio provides an indication of the relative changes in stress state in a layer that are induced by a given exposure to ions. A relatively higher stress response ratio will indicate that a relatively larger change in stress condition of an implanted layer will occur in response to the implanting ions. In particular, the term “stress response ratio” may refer to the change in stress state of a film after a particular amount of ion exposure. According to some embodiments of the disclosure, the stress response ratio may be expressed in terms of changes in ion dose at a given ion energy.

The stress response ratio may be quantified in one approach by determining stress response to a given implant (S_{I}) compared to a maximum theoretical stress response for the stress compensation layer (S_{M}). The determination of maximum theoretical stress response may be derived by determining of an integrated damage level that results in a maximum stress response. In particular embodiments, as detailed below, the value of SRR may be determined by determining the integrated damage in an SCL that is generated by a given implant in relation to a maximum integrated damage threshold, beyond which damage threshold further damage does not alter a stress state in the SCL.

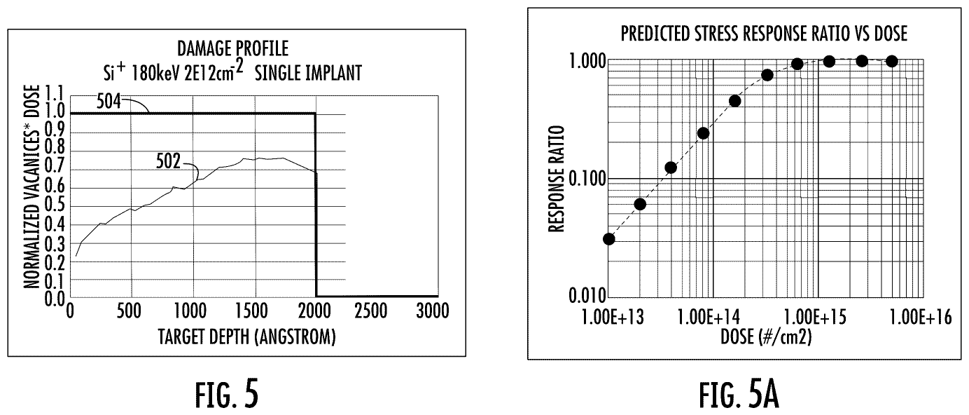

FIG. 5 presents a graphical representation of how stress response ratio is determined. The curve 504 represents the integrated damage threshold (normalized to a value of 1) beyond which threshold any further implant damage, such as additional vacancies, does not generate further changes in stress in the SCL. The area under the curve 504 may thus be considered to represent S_{M} for a 2000 Å thick SiN layer acting as an SCL. The value of S_{I} for FIG. 5 would correspond to the stress response induced by a single implant of Si⁺ ions having an ion energy of 180 keV and implanted to a dose of 2E14/cm² into the 2000 Å thick SiN layer. Thus, the SRR for the single implant example of FIG. 5 is equal to a ratio of the area under curve 502 (S_{I}) to the area under curve 504 (S_{M}). Thus, in the example of FIG. 5, the value of SRR may be approximately 0.55.

FIG. 5A plots the dependence of the Stress response ratio as a function of total ion dose. As exhibited, the stress response ratio saturates above approximately 7E14 cm⁻². Thus, after a stress control layer that has already received a dose of 7E14 cm⁻², exposing the stress control layer to additional ion implantation will not further reduce stress within the stress control layer.

Referring also to FIG. 4, the integrated area under each curve is used to calculate the stress response ratio (SRR) for that particular ion dose. In FIG. 4, the damage is expressed as normalized vacancies as noted, where the value of normalized vacancies by definition does not exceed 1. Note that for a given ion implantation procedure, the variation of SRR with ion dose will depend upon the ion energy of implanting ions. The SRR will also depend upon whether the ion implantation procedure involves a single implant, conducted under just one implant condition (that is, same ion energy, same ion species, etc.) or whether the ion implantation procedure involves multiple implants to generate a given ion dose, where the multiple implants use different ion energy, or otherwise vary the implant conditions.

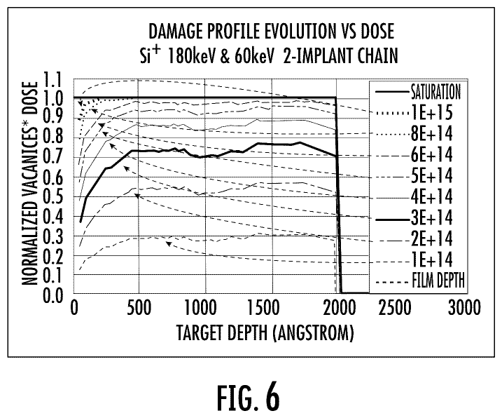

With this in mind, the present inventors have discovered that a tailored set of multi-implant procedures may generate more efficient route to generate defects and thus stress relaxation within a given layer. FIG. 6 is a graph that illustrates the use of a two-implant chained ion implantation approach to achieve more efficient defect saturation within a layer, according to embodiments of the disclosure. In particular, as with FIG. 4, the graph plots a simulation of the normalized vacancies generated by Si ion implantation as a function of depth within a 2000 A thick SiN layer. The chained implant is formed as the sum of two implants, where one implant is performed at 60 keV to implant Si ions into the silicon nitride layer at a relatively shallower depth, while another implant is performed at 180 keV to implant Si ions into the silicon nitride layer at a relatively deeper depth. Each curve in FIG. 6 represents the damage profile after a given total dose of ions is implanted, formed from the sum of the two different implants, where the SRR is calculated from the area under each curve. Note that depending upon the exact combination of ion energies used in a chained implant procedure, for a given total ion dose, the uniformity of damage distribution may improve with respect to a single energy implant procedure. In addition, in a multi-energy chained implant procedure, for a given ion dose, the value of SRR may exceed the SRR value achieved using a single implant. In particular, the chained implant approach may be more efficient in saturating damage at shallower depths than the single implant approach.

In operation, for a targeted value of SRR, a chained implant procedure may be determined in order to realize that targeted value. To explain further the operations related to a chained implant procedure and use of SRR information for processing a stress compensation layer (SCL), FIG. 1A shows further details of the controller 50. In this embodiment, the controller 50 may include a processor 52, such as a known type of microprocessor, dedicated processor chip, general purpose processor chip, or similar device. The controller 50 may further include a memory or memory unit 54, coupled to the processor 52, where the memory unit 54 contains a chained implant routine 56. The chained implant routine 56 may be operative on the processor 52 to manage an implant process using the ion beam 18 and substrate 100 in order to impart an amount of damage, such as specified by SRR into a stress compensation layer, as discussed above. The memory unit 54 may comprise an article of manufacture. In one embodiment, the memory unit 54 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

In some implementations, the memory unit 54 may receive and/or store stress information related to the substrate/stress compensation layer, as discussed above, for a given wafer or set of wafers. In some implementations, the memory unit may store information related to SRR values for given combinations of ion type/ion energy/ion dose/stress compensation layer/substrate, and so forth. The SRR values may be stored in any suitable format including databases, tabular form, etc., and may include pre-stored SRR values determined for a matrix of suitable ion energies, ion doses, layer thicknesses, etc., including those values that may be applicable during a given dynamic implant. The measured or calculated stress on a wafer may then be used to determine a chained implant recipe to be implemented on the wafer to compensate for the stress pattern. In some implementations, the chained implant routine 56 may calculate a best chained implant recipe to perform, including a best combination of ion energy and ion dose for each implant of a plurality of implants. Suitable criteria for selection of the chained implant recipe may include most efficient use of ion dose to generate the target SRR, a target uniformity in the damage profile as a function of depth, etc.

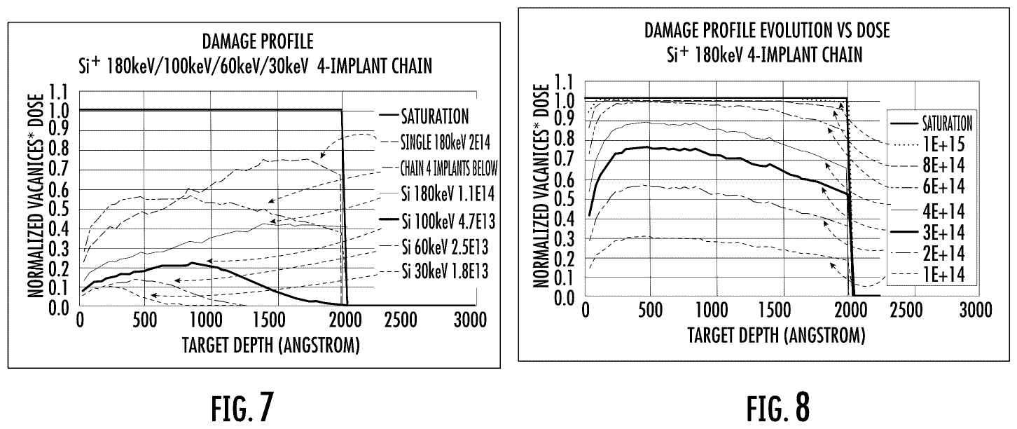

FIG. 7 is a graph that illustrates the use of complementary implants according to additional embodiments of the disclosure to improve distribution of damage within a layer. As with FIG. 3, the graph plots a simulation of the normalized vacancies generated by Si ion implantation as a function of depth within a 2000 A thick SiN layer. The total dose of the chained implant is 2E14/cm³. In this case, the chained implant is formed as the sum of four implants, where one implant is performed at 30 keV to implant a dose of 1.8E13/cm² Si ions into the silicon nitride layer; another implant is performed at 60 keV to implant a dose of 2.5 E13/cm² Si ions; a further implant at 100 keV to implant a dose of 4.7E13/cm² Si ions into the silicon nitride layer; and an additional implant is performed at 180 keV to implant a dose of 1.1E14/cm² Si ions into the silicon nitride layer. The lower energy implants, as indicated by the lower curves, generate damage profiles that peak in concentration at relatively shallower depths, less than 1000 A depth from the upper surface of the SiN layer. The highest energy implant generates a damage profile peaks in concentration at approximately 1600 A depth. Together, the chained implant, representing the sum of the four profiles, generates a composite damage profile that is a relatively flat damage profile between approximately 300 A and 1400 A depth, with a sharp decrease at depths below 200 A and a relatively gradual decrease at depths above 1400 A. For comparison, FIG. 7 also shows the curve that represents the damage profile induced after a single implant of 2E14/cm² Si ions at an energy of 180 keV.

FIG. 8 is a graph that illustrates the use of the four-implant chained ion implantation approach of FIG. 7 to achieve more efficient defect saturation within a layer, according to embodiments of the disclosure. In particular, as with FIG. 4, and FIG. 6, the graph plots a simulation of the normalized vacancies generated by Si ion implantation as a function of depth within a 2000 A thick SiN layer. Each curve in FIG. 8 represents the damage profile after a given total dose of ions is implanted, formed from the sum of the four different implants, described with respect to FIG. 7. Note that in this approach, after a total dose of 6E14/cm² is implanted, the normalized vacancy level is above 0.9 down to a depth of ˜1750 A, save for the top 100 Å of the SiN layer. Thus, this four-implant chained implant approach may reduce the total ion dose needed to achieve a uniform vacancy distribution at a high level, achieving a more optimum stress relief in a layer with less total ion current. In this example, with respect to the results of the two-implant approach of FIG. 6, a normalized vacancy value above 0.9 is achieved at relatively shallower depths, at the expense of less normalized vacancy values at the depths above ˜1750 A.

Again, this multi-implant chained implant approach may be harnessed to generate a more efficient route to achieve maximum normalized vacancy state. In various embodiments, before implementing an implant procedure, for a given ion/stress compensation layer combination, SRR values may be conveniently calculated using known approaches and may be pre-stored for a matrix of suitable ion energies, ion doses, layer thicknesses, etc., that may be applicable during an implant. Moreover, in some implementations, these SRR values may be calculated for a series of ion doses, based upon chain implant combinations, such as discussed above with respect to FIG. 6. Note that this approach provides a manner to more efficiently achieve a targeted change in stress by tailoring the implant procedure, such as using a chained implant recipe involving two implant energies, or four implant energies. In other words the targeted stress change may be achieved for a lower total ion dose implanted into a film by partitioning the dose into implants at multiple different energies rather than a single energy.

Note that one concern engendered by the implementation of the chained-implant procedures described above, is that these procedures entail changing the ion energy between the different constituent implants that may up a given chained implant process. In a beamline ion implanter, changing the ion energy of the implanting ions may entail retuning the ion source and/or other beamline components. Thus, the overall throughput of such an approach may be affected. In an approach for implantation into a stress compensation layer that employs a single ion energy, such retuning is not needed.

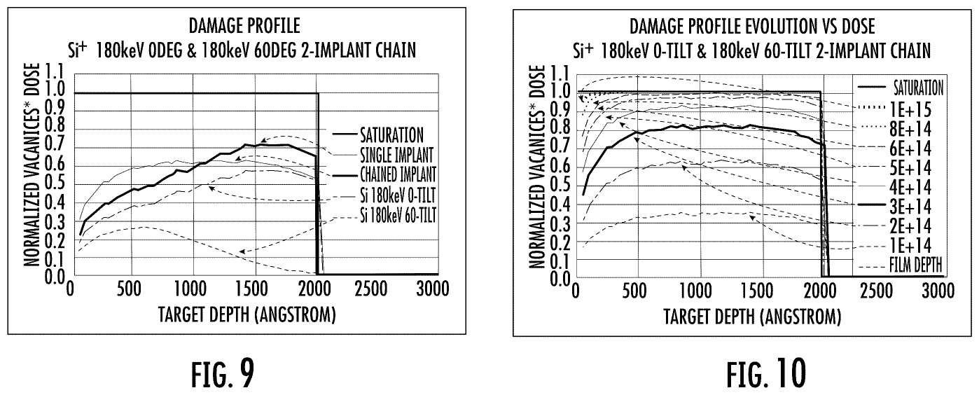

FIG. 9 is a graph that illustrates the use of complementary implants according to additional embodiments of the disclosure to improve distribution of damage within a layer. As with FIG. 3, and FIG. 7 the graph plots a simulation of the normalized vacancies generated by Si ion implantation as a function of depth within a 2000 A thick SiN layer. The total dose of the chained implant is 2E14/cm³. In this case, the chained implant is formed as the sum of two implants, where one implant is performed at 180 keV to implant a dose of 1.6E14/cm² Si ions into the silicon nitride layer at normal incidence to the main plane of the substrate, while the other implant is performed at 180 keV to implant a dose of 4E13/cm² Si ions at a 60 tilt angle of inclination with respect to a normal to the main plane of the substrate. The lower curve is a damage profile that reflects the normalized vacancy distribution as a function of depth in the SiN film, where the peak in the damage profile is skewed toward the top of the layer, at approximately 500 A. The damage profile curve for the normal incidence implant procedure exhibits a peak towards 1600 A in depth. The chained implant curve, represents the sum of these two implants, and exhibits a relatively flat damage profile between depths of 500 A to 1700 A. Note that for this particular ion dose and ion energy, the area under the respective curves, representing the SRR, is slightly less for a single implant at normal incidence as compared to the chained implant using two different tilt angles of incidence. Moreover, the distribution of vacancies as a function of depth is substantially more uniform in the chained implant case.

The multiple-tilt-angle-chained implant approach of FIG. 9 may be employed to effect a more efficient defect saturation within a stress compensation layer. FIG. 10 is a graph that displays the results of such an approach according to further embodiments of the disclosure. In particular, as with FIG. 4, and FIG. 6, and FIG. 8 the graph plots a simulation of the normalized vacancies generated by Si ion implantation as a function of depth within a 2000 A thick SiN layer. Each curve in FIG. 10 represents the damage profile after a given total dose of ions is implanted, formed from the sum of the two different implants, described with respect to FIG. 9. Note that in this approach, after a total dose of 5E14/cm² is implanted, the normalized vacancy level is above 0.9 at depths greater than 200 A. Thus, a high vacancy saturation (where ‘high” may mean above 0.9) is achieved for all but the top 10% of the layer at relatively lower total ion dose as compared to the single implant approach of FIG. 4. Moreover, this approach has the added advantage that the two implants are performed at the same energy, so that no retuning of the ion source or beamline components is required between implants, resulting in improved productivity. While the above example illustrates two implants, in additional embodiments three or more implants may be used where the tilt angle is different for each implant, in order to further tailor damage profiles, efficiency of damage generation as a function of total ion dose, and so forth.

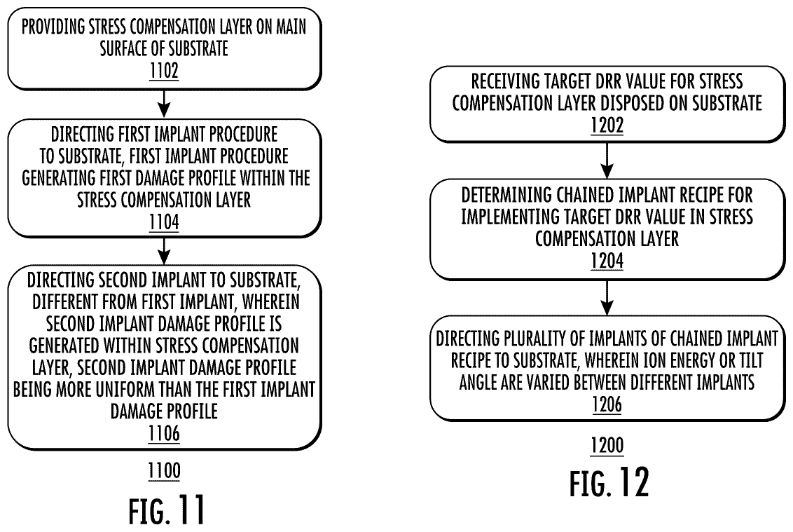

Turning now to FIG. 11, there is shown a process flow 1100, according to some embodiments of the disclosure. At block 1102, a stress compensation layer is provided on a main surface of a substrate, such as a silicon wafer. The stress compensation layer may be provided on a main surface opposite to a second main surface where device processing is to take place or is taking place on the substrate. In some non-limiting embodiments, the stress compensation layer may be a silicon nitride film.

At block 1104, a first implant procedure is directed to the substrate. The first implant procedure may generate a first damage profile within the stress compensation layer. In some embodiments, the first implant procedure may involve implanting a dose of ions at a given ion energy and a given angle of incidence as defined by a tilt angle of the substrate. In some embodiments, the angle of incidence of the ions may be along a perpendicular to the main surface of the substrate. The first implant may generate a first damage profile within the stress compensation layer, as embodied in a normalized vacancy distribution as a function of thickness within the stress compensation layer.

At block 1106, a second implant is directed to the substrate that is different from the first implant. The second implant may generally differ from the first implant in ion energy or angle of incidence, according to some non-limiting embodiments. As such, a composite damage profile is generated within the stress compensation layer after the second implant, where the composite damage profile is a result of the first and second implants. The composite damage profile may be more uniform than the first implant damage profile.

Turning now to FIG. 12, there is shown a process flow 1200, according to some other embodiments of the disclosure. At block 1202, a target stress response ratio (SRR) is received for a stress compensation layer provided on a main surface of a substrate, such as a silicon wafer. The stress response ratio may be defined as a ratio of an integrated damage generated by the ion beam as a function of depth through a thickness of a stress compensation layer (D_{I}), compared to a maximum integrated damage for the stress compensation layer D_{M}, wherein SRR=D_{I}/D_{M}.

At block 1204, a chained implant recipe is determined for implementing the target SRR within the stress compensation layer. The chained implant recipe may include at least two different implants that are to be performed under different implant conditions. The chained implant recipe may be a tailored set of multi-implant procedures that generate a more efficient route to generate defects and thus generate stress relaxation within a given layer.

At block 1206, a plurality of implants of the chained implant recipe are directed to the substrate, where ion energy or tilt angle are varied between different implants.

While the aforementioned embodiments may be employed to implant stress compensation layers that are provided on the back side of a substrate, in additional embodiments, the chained implantation variants as detailed herein above may be used to modify stress in a stress compensation layer provided on a front side of a substrate, where the front side of the substrate includes devices, circuits, active layers, or other components. In particular embodiments, the stress compensation layer may be provided on the front side of a substrate as a sacrificial layer, such as a hard mask that is used for patterning. An advantage of performing a chained implantation procedure on a frontside SCL, such as an existing sacrificial layer like a hard mask, is that the sacrificial layer may be used both for patterning as well as stress compensation.

Advantages provided by the present embodiments are multifold. As a first advantage, a desired stress response profile may be achieved with a relatively lower total implant dose as compared to known approaches, thus providing improved wafer throughput. In another advantage, by changing angle of incidence between successive implants in a chained implant, an improved stress response profile may be achieved using an ion implantation recipe that does not require returning ion source and various beamline components.

The present disclosure is not to be limited in scope by the specific embodiments described herein. Indeed, other various embodiments and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose, yet those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of stress management in a substrate, comprising:
providing a stress compensation layer on a main surface of the substrate; and
performing a chained implant procedure to implant a set of ions into the stress compensation layer, the chained implant procedure comprising:
directing a first implant procedure to the substrate, the first implant procedure generating a first damage profile within the stress compensation layer; and
directing a second implant to the substrate, different from the first implant, wherein a composite damage profile is generated within the stress compensation layer after the second implant, the composite damage profile resulting in a higher stress response ratio than the first damage profile.

2. The method of claim 1, wherein the stress response ratio is determined as a ratio of a stress response to a given implant (S_{I}) compared to a maximum theoretical stress response for the stress compensation layer (S_{M}).

3. The method of claim 1, wherein the first implant is performed at a first ion energy, and the second implant is performed at a second ion energy, different from the first ion energy.

4. The method of claim 1, wherein directing the first implant and the second implant comprise directing a beam of silicon ions to the substrate, and wherein the stress compensation layer comprises a silicon nitride material.

5. The method of claim 1, wherein the stress compensation layer is provided on a front side of the substrate, the front side of the substrate including on or more of: devices, circuits, and structures to be formed into devices or circuits.

6. The method of claim 5, wherein the stress compensation layer comprises an existing sacrificial patterning layer, disposed on the front side.

7. The method of claim 1, wherein the first implant is performed at a first incidence angle, and the second implant is performed at a second incidence angle, different from the first incidence angle.

8. The method of claim 7, wherein the implant procedure is completed after the second implant and no other implant is performed.

9. An ion implanter, comprising:
an ion source to generate an ion beam;
an acceleration component to vary an ion energy of the ion beam; and
a controller, the controller comprising:
a processor; and
a memory unit coupled to the processor, including a chained implant routine, the chained implant routine operative on the processor to control the ion implanter to impart a composite damage profile into a stress compensation layer on a substrate by performing a plurality of implants at a plurality of different ion implant conditions,
wherein a first implant is to generate a first damage profile within the stress compensation layer, and
wherein a second implant is to generate a composite damage profile after the second implant, the composite damage profile having a higher stress response ratio than the first damage profile.

10. The ion implanter of claim 9,
the chained implant routine operative on the processor to control the ion implanter to receive a targeted value for a stress response ratio (SRR) for the stress compensation layer; and
calculate the composite damage profile based upon the targeted value for the SRR,
the stress response ratio determined as a ratio of a stress response to a given implant (S_{I}) compared to a maximum theoretical stress response for the stress compensation layer (S_{M}).

11. The ion implanter of claim 10, the chained implant routine operative on the processor to control the ion implanter to determine a combination of ion energy and ion dose for the first implant and for the second implant, based on a set of criteria.

12. The ion implanter of claim 11, the set of criteria comprising one or more of:
efficient use of ion dose to generate the targeted value for the SRR; and
a target uniformity in the composite damage profile, as a function of depth.

13. The ion implanter of claim 9, wherein the first implant is performed at a first ion energy, and the second implant is performed at a second ion energy, different from the first ion energy.

14. The ion implanter of claim 9, wherein directing the first implant and the second implant comprise directing a beam of silicon ions to the substrate.

15. The ion implanter of claim 9, wherein the stress compensation layer comprises a silicon nitride material, and the ion beam comprises silicon ions.

16. The ion implanter of claim 9, wherein the first implant is performed at a first incidence angle, and the second implant is performed at a second incidence angle, different from the first incidence angle.

17. The ion implanter of claim 9, wherein the stress compensation layer is provided on a front side of the substrate, the front side of the substrate including on or more of: devices, circuits, and structures to be formed into devices or circuits.

18. The ion implanter of claim 17, wherein the stress compensation layer comprises an existing sacrificial patterning layer, disposed on the front side.

19. A controller for an ion implanter, comprising:
a processor; and
a memory unit coupled to the processor, including a chained implant routine, the chained implant routine operative on the processor to control an ion implanter to impart a composite damage profile into a stress compensation layer on a substrate by:
performing a first implant under a first set of implant conditions; and
performing a second implant under a second set of implant conditions, different from the first set of implant conditions,
wherein the first implant is to generate a first damage profile within the stress compensation layer, and
wherein the second implant is to generate a composite damage profile after the second implant,
the composite damage profile resulting in a higher stress response ratio than the first damage profile.

20. The controller of claim 19,
the chained implant routine operative on the processor to control the ion implanter to receive a targeted value for a stress response ratio (SRR) for the stress compensation layer; and
calculate the composite damage profile based upon the targeted value for the SRR,
the stress response ratio determined as a ratio of a stress response to a given implant (S_{I}) compared to a maximum theoretical stress response for the stress compensation layer (S_{M}).
